(19) United States
(12) Patent Application Publication
(10) Pub. No.: US 2015/0137337 A1
(43) Pub. Date: May 21, 2015

(54) SEMICONDUCTOR PACKAGE AND LEAD FRAME

(71) Applicant: Siliconware Precision Industries Co., Ltd, Taichung (TW)

(72) Inventors: Tsung-Tien Hsieh, Taichung (TW); Wen-Jung Chiang, Taichung (TW)

(73) Assignee: Siliconware Precision Industries Co., Ltd, Taichung (TW)

(21) Appl. No.: 14/157,904

(22) Filed: Jan. 17, 2014

(30) Foreign Application Priority Data
Nov. 15, 2013 (TW) 102141608

(51) Int. Cl. H01L 23/495; H02B 1/20; H01L 23/31

(52) U.S. Cl. CPC H01L 23/49555; H01L 23/3107; H02B 1/20; H01L 23/49503
USPC 257/676; 174/261

(57) ABSTRACT

A semiconductor package is disclosed, which includes: a die paddle portion; a plurality of conductive portions circumventing the die paddle portion; a power bus bar and a ground bus bar formed around the periphery of the die paddle portion; a semiconductor element attached to the die paddle portion and electrically connected to the conductive portions, the power bus bar, and the ground bus bar by a plurality of bonding wires; and an encapsulant encapsulating the semiconductor element and the bonding wires. The ground bus bar extends outward along the power bus bar and is mutually configured with the power bus bar so as to reduce the loop inductance and resistance of the power bus bar while in use.

### BACKGROUND OF THE INVENTION

1. Field of the Invention

The present invention relates to semiconductor packages, and more particularly, to a semiconductor package having a lead frame with low electrical loop resistance and inductance.

2. Description of Related Art

Along with the development of electronic industries, many advanced electronic products are being developed toward the trend: devices with light-weight, thinness, shortness, and tininess characteristics. Accordingly, various package modules have been developed for semiconductor packaging For example, a QFP (Quad Flat Package) package, comprising a lead frame with short pitched leads, provides a plurality of power leads, signal leads and ground leads, which can be used in large scale or super large scale integrated circuit applications.

However, if a conventional QFP package is utilized in high-speed and high-frequency applications, it is inevitable that the number of the power leads and ground leads should be increased. Therefore, some signal leads must be changed into power leads and ground leads. FIG. 1A is a schematic cross-sectional view of a conventional semiconductor package 1 and FIG. 1A′ is a schematic upper view of the lead frame 10 of the semiconductor package 1. Referring to FIGS. 1A and 1A′, the semiconductor package 1 has a lead frame 10 having a die paddle 100 and a plurality of signal leads 101, power leads 102 and ground leads 103 circumventing the die paddle 100; a semiconductor chip 11 attached to the die paddle 100 and electrically connected to the signal leads 101, the power leads 102 and the ground leads 103 by a plurality of bonding wires 110; and an encapsulant 12 formed on the lead frame 10 for encapsulating the semiconductor chip 11 and the bonding wires 110.

On the other hand, along with the progress of semiconductor wafer processes, the semiconductor chip 11 also requires more high density circuit integration Therefore, the number of the signal leads 101 needs to be greatly increased, which, however, is limited by the power leads 102 and the ground leads 103 that occupy a lot of space. Therefore, the conventional semiconductor chip package has limited I/O count and functions.

Further, when the I/O count of the semiconductor chip 11 is increased, the number of the power leads 102 and the ground leads 103 also needs to be increased to provide stable electric current. However, limited by the number of the signal leads 101, it is difficult to provide a desired number of the power leads 102 and the ground leads 103, thereby adversely affecting the electrical performance of the semiconductor package 1.

Accordingly, another type of QFP packages is provided. FIGS. 1B is a schematic cross-sectional view of such a semiconductor package 1′, FIG. 1B′ is a schematic upper view of the lead frame 10′ of the semiconductor package 1′ and FIG. 1B″ is a partially perspective view of the semiconductor package 1′. Referring to FIGS. 1B to 1B″, a ground pad 103′ is formed around the periphery of the die paddle 100 to replace the above-described ground leads 103 and a plurality of power bus bars 104 are formed around the periphery of the die paddle 100 to replace the above-described power leads 102. As such, more space is available for the signal leads 101 and the number of the signal leads 101 can be increased. Relative to the position of the die paddle 100, the power bus bars 104 are higher than the ground pad 103′. The power bus bars 104 are usually applied in E-PAD QFP packages, LQFP (low profile QFP) packages or TQFP (Thin Quad Flat Package) packages.

However, in the semiconductor package 1′, although the number of the power bus bars 104 is less than the number of the power leads 102, the size of the power bus bars 104 is greater than the size of the power leads 102. Further, the size of the ground pad 103′ is greater than the size of the ground leads 103. As such, the inductance and resistance of the power bus bars 104 cannot be reduced. Therefore, when the semiconductor package is applied in high-speed electronic products, noises easily occur, thereby adversely affecting the electrical performance of the electronic products.

Further, since the semiconductor chip 11, the power bus bars 104 and the ground pad 103′ form a long return path, the inductance effect of the QFP package cannot be effectively reduced.

Therefore, there is an urgent need to provide a semiconductor package and a lead frame so as to overcome the above-described drawbacks.

### SUMMARY OF THE INVENTION

In view of the above-described drawbacks, the present invention provides a semiconductor package, which comprises: a die paddle portion; a plurality of conductive portions circumventing the die paddle portion; a power bus bar formed around the periphery of the die paddle portion; a ground bus bar formed around the periphery of the die paddle portion, extending outward along the power bus bar and mutually configured with the power bus bar; a semiconductor element attached to the die paddle portion and electrically connected to the conductive portions, the power bus bar and the ground bus bar by a plurality of bonding wires; and an encapsulant encapsulating the semiconductor element and the bonding wires.

In an embodiment, both the power bus bar and the ground bus bar are present in the plural number. The ground bus bars can be commonly grounded together. The package can further comprise a ground ring pad formed around the periphery of the die paddle portion and electrically connected to the ground bus bars so as to form a common electrical ground. Relative to the position of the die paddle portion, the ground ring pad can be lower than or flush with the ground bus bars or the power bus bars, and the power bus bars can be higher than or flush with the ground bus bars.

In an embodiment, the bonding wires electrically connect the semiconductor element to the power bus bar and the ground bus bar so as to cause the power bus bar to be shielded by the ground bus bar.

In an embodiment, the die paddle portion is exposed from the encapsulant. The present invention further provides a lead frame, which comprises: a die paddle portion; a plurality of conductive portions circumventing the die paddle portion; a power bus bar formed around the periphery of the die paddle portion; and a ground bus bar formed around the periphery of the die paddle portion, extending outward along the power bus bar and mutually configured with the power bus bar, wherein, relative to the position of the die paddle portion, the power bus bar is higher than or flush with the ground bus bar.

In an embodiment, the lead frame further comprises a ground ring pad formed around the periphery of the die paddle portion, wherein, relative to the position of the die paddle portion, the ground ring pad is lower than or flush with the ground bus bar or the power bus bar.

In an embodiment, both the power bus bar and the ground bus bar are present in plurality.

In the above-described package and lead frame, the ground bus bar and the power bus bar can be positioned adjacent to each other.

In the above-described package and lead frame, the die paddle portion can have at least three edges and the power bus bar can be positioned at at least one of the edges of the die paddle portion.

In the above-described package and lead frame, the power bus bar can have a base portion and two connecting portions bent, extending from two ends of the base portion.

In the above-described package and lead frame, the die paddle portion can be lower than, higher than or flush with the conductive portions.

According to the present invention, the ground bus bar extends outward from the power bus bar and is mutually configured with the power bus bar so as to reduce the return path of the circuit and reduce the inductance and resistance of the power bus bar and the number of the power bus bar, thereby improving the electrical performance of the semiconductor package.

### BRIEF DESCRIPTION OF DRAWINGS

FIG. 1A is a schematic cross-sectional view of a conventional semiconductor package;

FIG. 1A′ is a schematic upper view of the lead frame of FIG. 1;

FIG. 1B is a schematic cross-sectional view of another conventional semiconductor package;

FIG. 1B′ is a schematic upper view of the lead frame of FIG. 1B;

FIG. 1B″ is a partially perspective view of the semiconductor package of FIG. 1B;

FIGS. 2A and 2A′ are schematic cross-sectional views showing semiconductor packages according to different embodiments of the present invention;

FIG. 2B is a partially perspective view of the semiconductor package of FIG. 2A;

FIG. 2C is a partially upper view of the lead frame of FIG. 2A;

FIG. 3A is a schematic cross-sectional view of a semiconductor package according to another embodiment of the present invention;

FIG. 3A′ is a schematic upper view of the lead frame of FIG. 3A, wherein the cross-sectional view of the lead frame of FIG. 3A is taken along a sectional line A-A of FIG. 3A′; and

FIG. 3B is a partially perspective view of the semiconductor package of FIG. 3A.

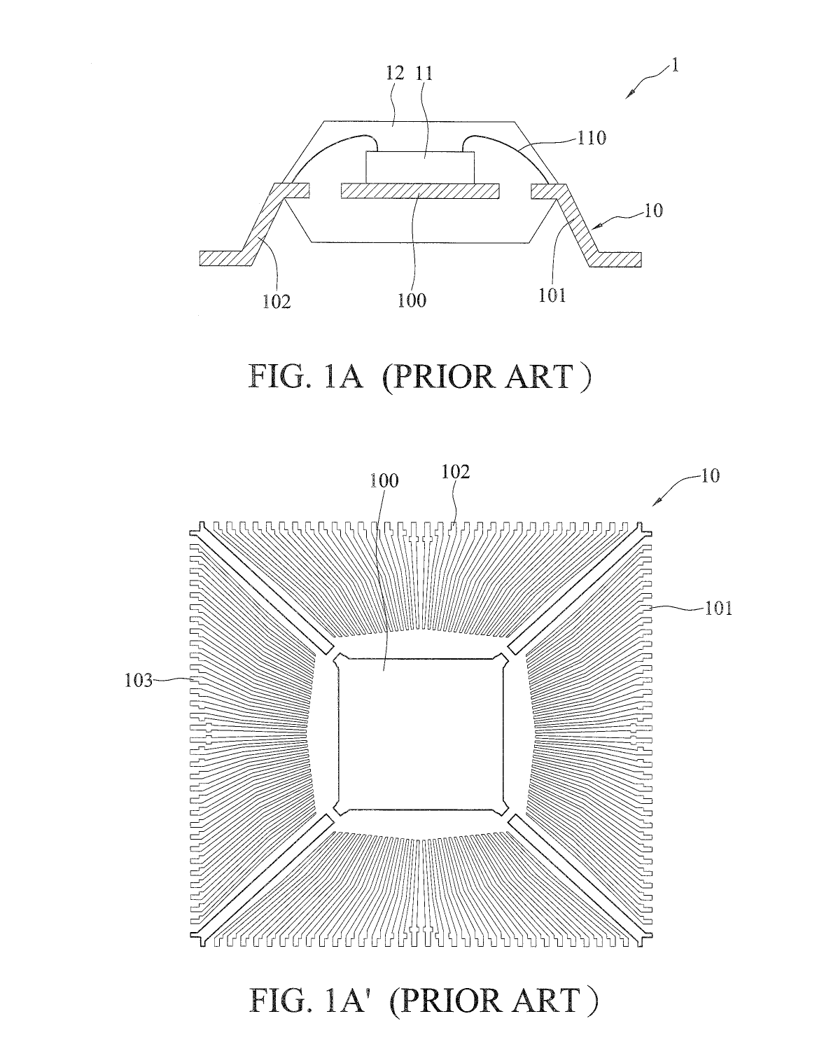

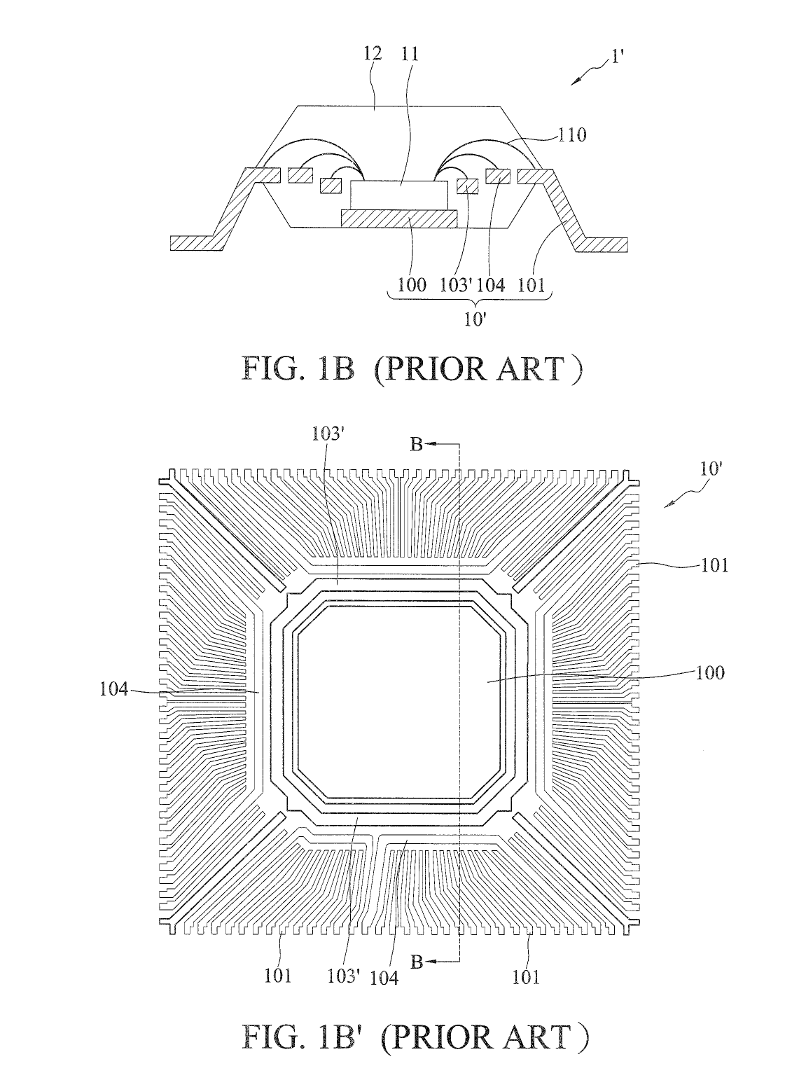

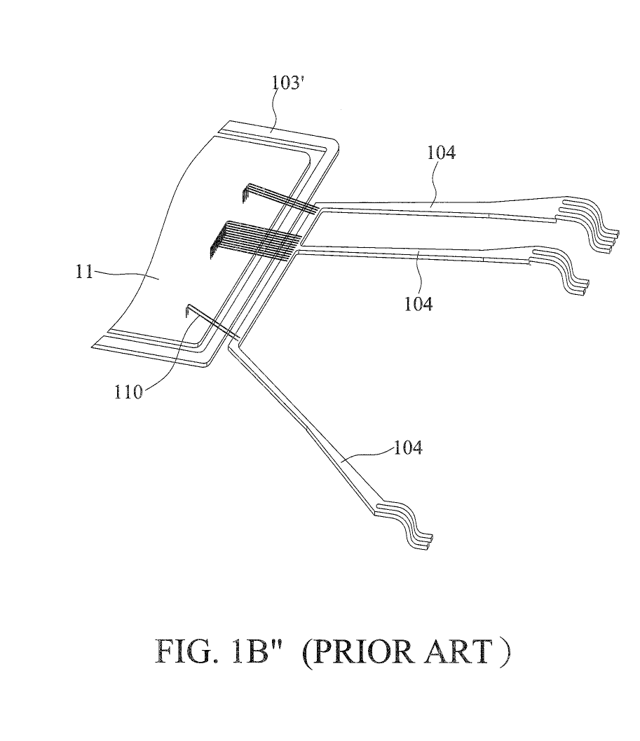

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “on”, “a” etc. are merely for illustrative purposes and should not be construed to limit the scope of the present invention.

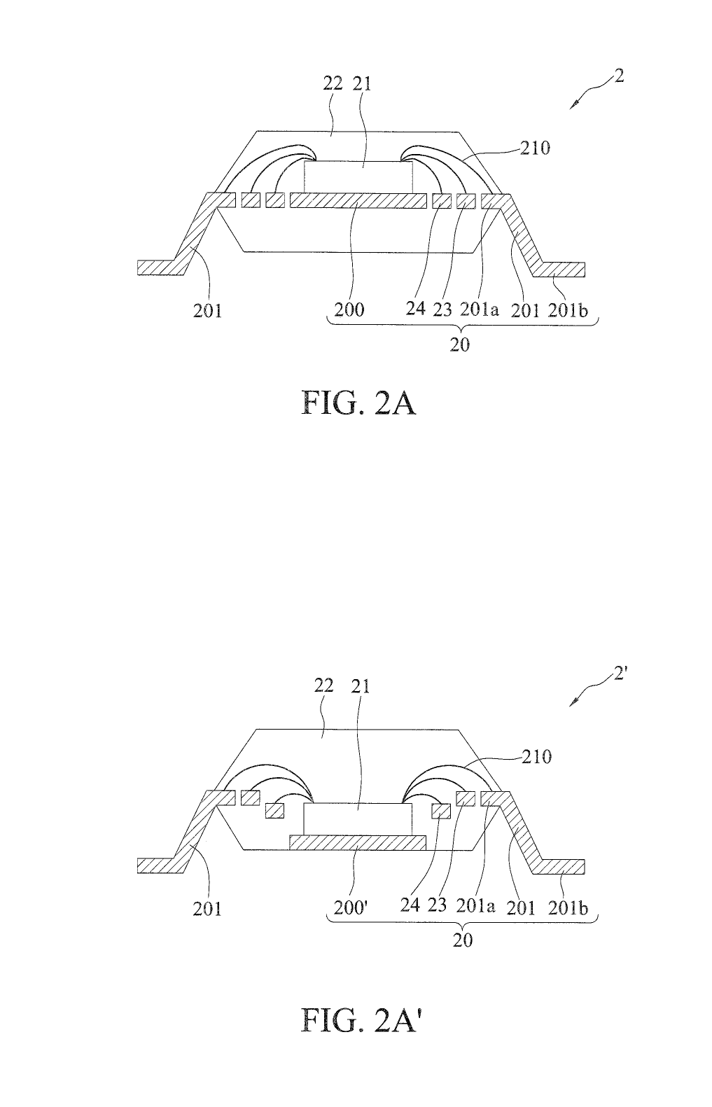

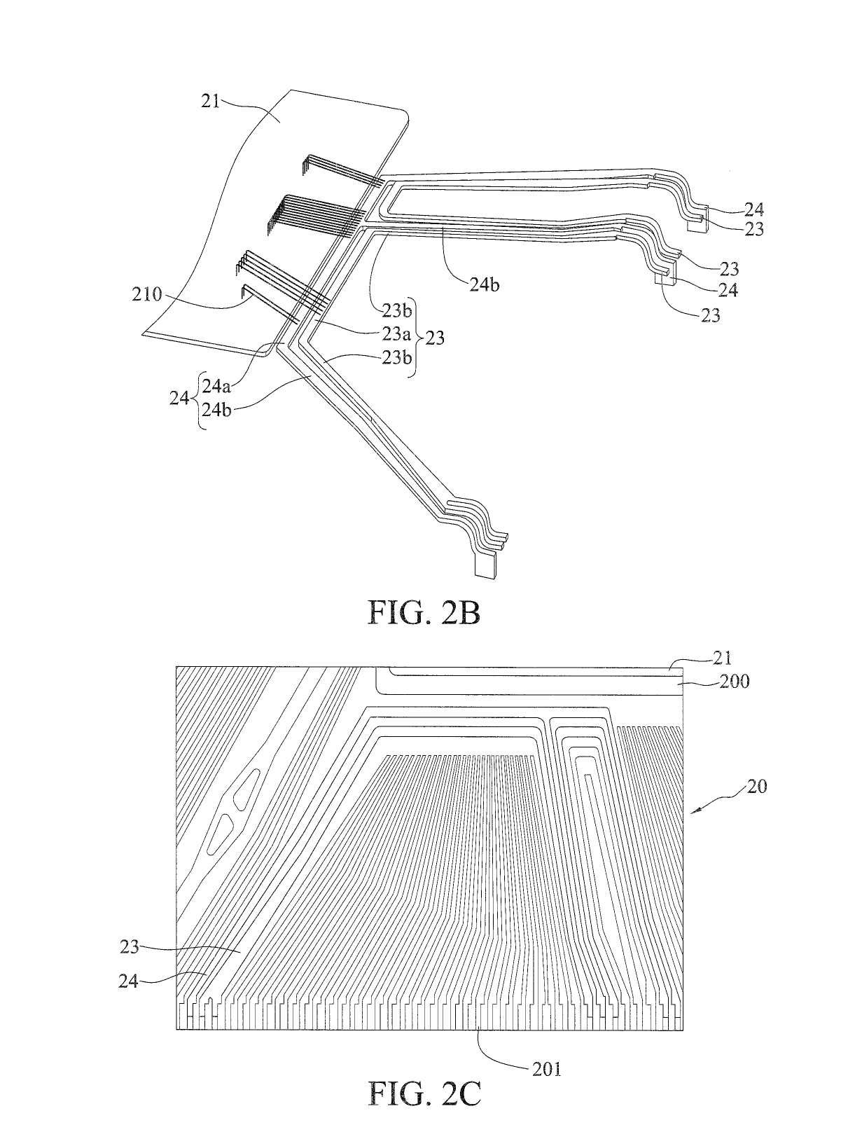

FIGS. 2A to 2C show a semiconductor package 2 of the present invention. Referring to FIGS. 2A to 2C, the semiconductor package 2 has a lead frame 20, a semiconductor element 21 disposed on the lead frame 20 and an encapsulant 22 encapsulating the semiconductor element 21.

The lead frame 20 has a die paddle portion 200, and a plurality of conductive portions 201 (i.e., leads), a power bus bar 23 and a ground bus bar 24 circumventing the die paddle portion 200. The ground bus bar 24 extends outward along the power bus bar 23 and is mutually configured with the power bus bar 23. Further, both the power bus bar 23 and the ground bus bar 24 can be present in the plural number. In addition, the die paddle portion 200 is encapsulated by the encapsulant 22.

Relative to the position of the die paddle portion 200, the power bus bar 23 is flush with the ground bus bar 24.

In another embodiment, referring to FIG. 2A′, the die paddle portion 200′ of the semiconductor package 2′ is exposed from the encapsulant 22. Further, relative to the position of the die paddle portion 200′, the power bus bar 23 is higher than the ground bus bar 24.

Furthermore, the die paddle portion 200, 200′ can be lower than, higher than or flush with inner leads 201a of the conductive potions 201.

The semiconductor element 21 is attached to the die paddle portion 200 and electrically connected to the conductive portions 201, the power bus bar 23 and the ground bus bar 24 by a plurality of bonding wires 210.

The encapsulant 22 is formed on the lead frame 20 for encapsulating the semiconductor element 21, the inner leads 201a and the bonding wires 210. The outer leads 201b of the conductive portions 201 extend outward from the encapsulant 22.

In the present embodiment, the power bus bar 23 is wider than at least portions of the conductive portions 201. Also, the ground bus bar 24 can be wider than at least portions of the conductive portions 201. In other embodiments, the power bus bar 23 and the ground bus bar 24 is not wider than at least portions of the conductive portions 201.

Preferably, the ground bus bar 24 and the power bus bar 23 are positioned adjacent to each other and extend outward so as to increase the return current of I/O circuit of the semiconductor element 21 and shorten the return electrical path, thereby effectively reducing the inductance effect of the semiconductor package 2.

Further, the bonding wires 210 electrically connect the semiconductor element 21 to the power bus bar 23 and the ground bus bar 24 such that the power bus bar 23 is shielded by the ground bus bar 24, thus preventing the power bus bar 23 from interfering with signals of the conductive portions 201.

The conductive portions 201 are signal leads. The power bus bar 23 has a first base portion 23a and two first connecting portions 23b bent, extending from two ends of the first base portion 23a. As such, the power bus bar 23 has a horseshoe shape, an inverted-U shape and so on. The ground bus bar 24 has a second base portion 24a and two second connecting portions 24b. The bonding wires 210 are bonded to the first base portion 23a and the second base portion 24a, and the first connecting portions 23a and the second connecting portions 24b are connected to an external device such as a circuit board.

The ground bus bar 24 replaces the conventional ground pad. The ground bus bar 24 and the power bus bar 23 are mutually configured with each other and extend outward such that the number of the power bus bar 23 and the size of the ground bus bar 24, and hence the inductance and resistance of the power bus bar 23, are reduced. Therefore, the present invention can be applied in high-speed electronic products to achieve reduced inductance and resistance values, thereby reducing noises and improving the electrical performance of the electronic products.

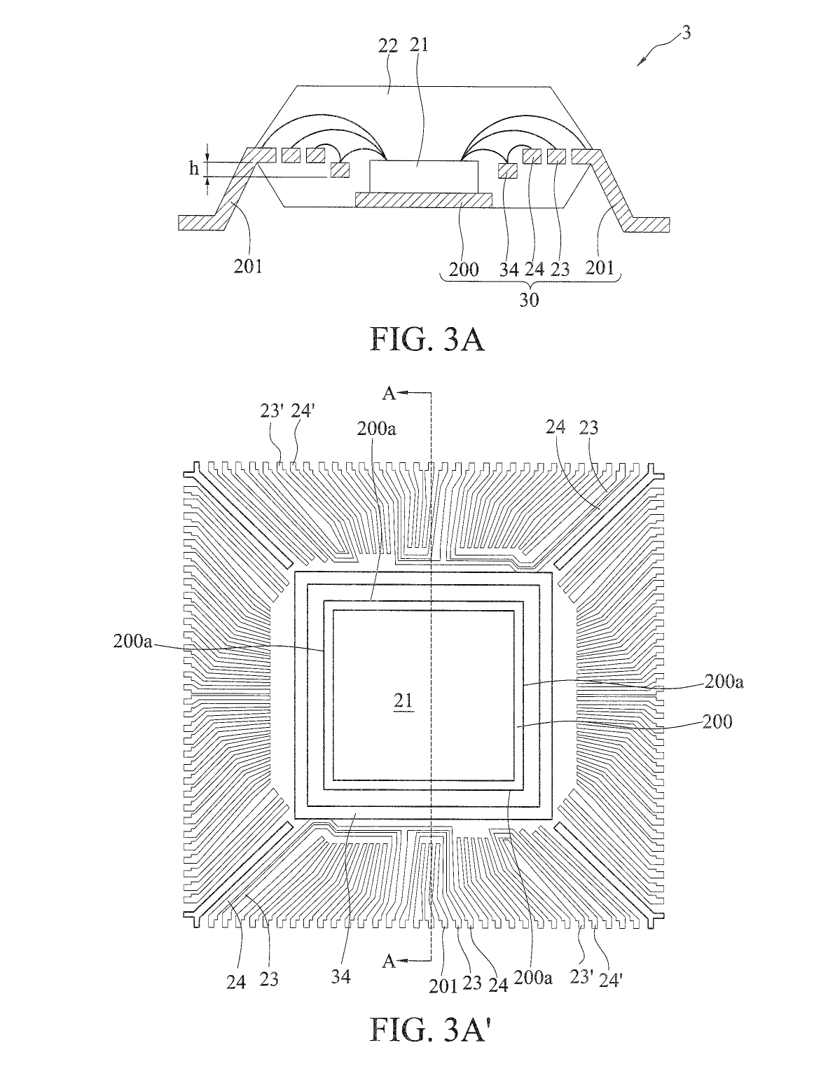

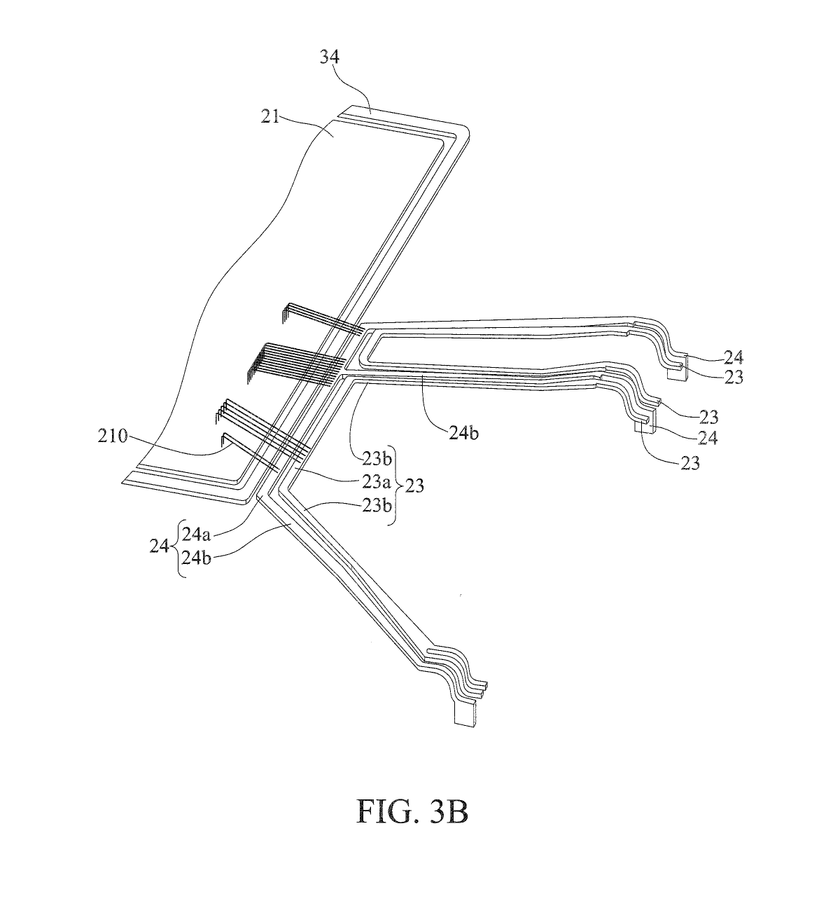

FIGS. 3A to 3B show another embodiment of the semiconductor package of the present invention. In the present embodiment, various kinds of power bus bars can be provided for power sources with different voltages or currents.

Referring to FIG. 3A′, the die paddle portion 200 has four edges 200a. A plurality of power bus bars 23, 23′ and a plurality of ground bus bars 24, 24′ mutually configured with the power bus bars 23, 23′ are formed at two opposite edges 200a of the die paddle portion 200. Further, a ground ring pad 34 is formed around the periphery of the die paddle portion 200. The ground ring pad 34 is connected to portions of the ground bus bars 24, 24′ directly or by bonding wires (not shown). In addition, the ground ring pad 34 can form a common electrical ground along with the ground bus bars 23, 23′. The two groups of the power bus bars 23, 23′ are provided for power sources with different voltages or currents. It should be noted that the configuration of the power bus bars is not limited to the present embodiment. For example, more groups of the power bus bars can be provided, and the power bus bars can be disposed at two adjacent edges 200a of the die paddle portion 200.

Further, the positions of the power bus bars 23, 23′ and the ground bus bars 24, 24′ are interchangeable.

Relative to the position of the die paddle portion 200, the power bus bars 23, 23′ are flush with the ground bus bars 24, 24′, and the ground ring pad 34 is lower than the ground bus bars 24, 24′ or the power bus bars 23, 23′ with a height difference h therebetween. Alternatively, the power bus bars 23, 23′can be flush with the ground bus bars 24, 24′.

It should be noted that the relative positions of the die paddle portions 200, 200′, the power bus bars 23, 23′, the ground bus bars 24, 24′ and the conductive portions 201 can be modified according to the practical need without being limited to above-described embodiments.

The present invention further provides a lead frame 20, 30, which has: a die paddle portion 200, 200′; a plurality of conductive portions 201, i.e., leads circumventing the die paddle portion 200, 200′; a power bus bar 23, 23′ formed around the periphery of the die paddle portion 200, 200′; and a ground bus bar 24, 24′ formed around the periphery of the die paddle portion 200, 200′, extending outward along the power bus bar 23, 23′ and mutually configured with the power bus bar 23, 23′.

The die paddle portion 200, 200′ is lower than, higher than or flush with inner leads 201a of the conductive portions 201.

Relative to the position of the die paddle portion 200, 200′, the power bus bar 23, 23′ is higher than or flush with the ground bus bar 24, 24′.

In an embodiment, the ground bus bar 24, 24′ and the power bus bar 23, 23′ are positioned adjacent to each other.

In an embodiment, the die paddle portion 200 has at least three edges 200a and the power bus bar 23, 23′ is positioned at at least one of the edges 200a of the die paddle portion 200.

In an embodiment, the power bus bar 24 has a first base portion 23a and two first connecting portions 23b bent, extending from two ends of the first base portion 23a.

In an embodiment, the lead frame 30 further has a ground ring pad 34 formed around the periphery of the die paddle portion 200. Relative to the position of the die paddle portion 200, the ground ring pad 34 is lower than or flush with the ground bus bar 24, 24′ or the power bus bar 23, 23′.

According to the present invention, the ground bus bar extends outward from the power bus bar and is mutually configured with the power bus bar so as to reduce the return electrical path of the circuit and reduce the inductance and resistance of the power bus bar and the number of the power bus bar, thereby improving the electrical performance of the semiconductor package.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a die paddle portion;
a plurality of conductive portions circumventing the die paddle portion;
a power bus bar formed around a periphery of the die paddle portion;
a ground bus bar formed around the periphery of the die paddle portion, extending outward along the power bus bar and mutually configured with the power bus bar;
a semiconductor element attached to the die paddle portion and electrically connected to the conductive portions, the power bus bar and the ground bus bar by a plurality of bonding wires; and
an encapsulant encapsulating the semiconductor element and the bonding wires.

2. The package of claim 1, wherein the ground bus bar and the power bus bar are positioned adjacent to each other.

3. The package of claim 1, wherein the bonding wires electrically connect the semiconductor element to the power bus bar and the ground bus bar so as to cause the power bus bar to be shielded by the ground bus bar.

4. The package of claim 1, wherein the die paddle portion has at least three edges and the power bus bar is positioned at at least one of the edges.

5. The package of claim 1, wherein the power bus bar has a base portion and two connecting portions bent, extending from two ends of the base portion.

6. The package of claim 1, wherein both the power bus bar and the ground bus bar are present in plurality.

7. The package of claim 6, wherein the ground bus bars are commonly grounded together.

8. The package of claim 7, further comprising a ground ring pad formed around the periphery of the die paddle portion and electrically connected to the ground bus bars so as to form a common electrical ground.

9. The package of claim 8, wherein, relative to the position of the die paddle portion, the ground ring pad is lower than or flush with the ground bus bars or the power bus bars, and the power bus bars are higher than or flush with the ground bus bars.

10. The package of claim 1, wherein the die paddle portion is lower than, higher than or flush with the conductive portions.

11. The package of claim 1, wherein the die paddle portion is exposed from the encapsulant.

12. A lead frame, comprising:
a die paddle portion;
a plurality of conductive portions circumventing the die paddle portion;
a power bus bar formed around the periphery of the die paddle portion; and
a ground bus bar formed around the periphery of the die paddle portion extending outward along the power bus bar and mutually configured with the power bus bar, wherein, relative to the position of the die paddle portion, the power bus bar is higher than or flush with the ground bus bar.

13. The lead frame of claim 12, wherein the ground bus bar and the power bus bar are positioned adjacent to each other.

14. The lead frame of claim 12, wherein the die paddle portion has at least three edges and the power bus bar is positioned at least one of the edges.

15. The lead frame of claim 12, wherein both the power bus bar and the ground bus bar are present in plurality.

16. The lead frame of claim 12, wherein the power bus bar has a base portion and two connecting portions bent, extending from two ends of the base portion.

17. The lead frame of claim 12, further comprising a ground ring pad formed around the periphery of the die paddle portion, wherein, relative to the position of the die paddle portion, the ground ring pad is lower than or flush with the ground bus bar or the power bus bar.

18. The lead frame of claim 12, wherein the die paddle portion is lower than, higher than or flush with the conductive portions.
